(19) United States
(12) Patent Application Publication
(10) Pub. No.: US 2013/0257510 A1
(43) Pub. Date: Oct. 3, 2013

(54) HIGH FREQUENCY SWITCH CIRCUIT

(71) Applicant: PANASONIC CORPORATION, Osaka (JP)

(72) Inventors: Hidefumi SUZAKI, Shiga (JP); Takahito MIYAZAKI, Kyoto (JP)

(21) Appl. No.: 13/790,585

(22) Filed: Mar. 8, 2013

Related U.S. Application Data
(63) Continuation of application No. PCT/JP2011/000423, filed on Jan. 26, 2011.

(30) Foreign Application Priority Data
Oct. 18, 2010 (JP) 2010-233946

(51) Int. Cl. H03K 17/0412

(52) U.S. Cl. CPC H03K 17/04123
USPC 327/374

(57) ABSTRACT

A high frequency switch circuit including: a first rectifier circuit including at least one rectifier element having one end connected between the gate terminal of a first MOSFET circuit and a first control terminal and the other end connected to ground, and a second rectifier circuit including at least one rectifier element having one end connected between the gate terminal of a second MOSFET circuit and a second control terminal and the other end connected to ground. The circuit further includes a connecting section connecting the forward-current input terminal side of at least one of the rectifier elements of the first rectifier circuit and one of the main terminal sides of the first MOSFET circuit, and connecting the forward-current input terminal side of at least one of the rectifier elements of the second rectifier circuit and one of the main terminal sides of the second MOSFET circuit.

This is a continuation application under 35 U.S.C. 111(a) of pending prior International Application No. PCT/JP2011/000423, filed on Jan. 26, 2011.

### BACKGROUND OF THE INVENTION

1. Field of the Invention

The present invention generally relates to high frequency switch circuits. More particularly, the present invention relates to the high frequency switch circuit that is mounted in small, lightweight and low power consumption mobile communication devices such as cellular phones.

2. Description of the Related Art

Mobile communication devices such as cellular phones employ high frequency switch circuits in order to switch transmission paths of high frequency signal such as switching transmission paths for an antenna between transmitting and receiving. These high frequency switch circuits are required to be smaller and lower in power consumption simultaneously on demand from cellular phones which are required to be smaller, lighter and lower in power consumption as well. Moreover, these high frequency switches have been required to be able to be mounted on integrated circuits whose outline would be 1 mm square level. In mounting these high frequency switch circuits on the small integrated circuits, it is helpful to reduce the number of terminals of switch circuits. In response, some switch circuits which do not need to attach a power supply terminal have been developed. For example, a high frequency switch circuit is already known that it has a configuration that utilizes the voltage applied to the control terminal for switching several transmission paths. (see, for example, Patent Literature Publications 1 and 2 below).

FIG. 7 shows a schematic configuration of a conventional high frequency switch circuit. The configuration in FIG. 7 shows the switch circuit disclosed in Patent Literature Publication 1, and the switch circuit is configured as an SPDT (single pole dual throw) switch circuit that makes use of a first control voltage to a first control terminal CT1 for controlling connection between a common signal terminal T3 and a first signal terminal T1 and/or a second control voltage to a second control terminal CT2 for controlling connection between the common signal terminal T3 and a second signal terminal T2, thereby to make a switch between the signal terminals T1 and T2 so that either the first signal terminal T1 or the second signal terminal T2 comes into connection with the common signal terminal T3. More specifically, in the switch circuit shown in FIG. 7, a first field effect transistor (FET) 101 and a second field effect transistor (FET) 102 are connected in series between the first signal terminal T1 and the second signal terminal T2 and the gate of the first FET 101 is connected to the first control terminal CT1 through a first resistor element 103 whereas the gate of the second FET 102 is connected to the second control terminal CT2 through a second resistor element 104. And, a first diode 105 and a second diode 106 are connected in series between the first control terminal CT1 and the second control terminal CT2, with their anodes common-connected. And, the point where the anode of the first diode 105 and the anode of the second diode 106 are common-connected and the point where the first FET 101 and the second FET 102 are common-connected are interconnected through a third resistor 107.

The switch circuit as shown in FIG. 7 employs GaAs MESFET (Metal-Semiconductor Field Effect Transistor) as the first and the second FETs 101 and 102. GaAs MESFET has better high frequency characteristics and lower power consumption characteristics, and it employs Schottky junction metal as a gate terminal. This FET configured by a Schottky junction metal and a semiconductor presents a diode characteristic between its gate and source. For example, if a positive voltage beyond the threshold of the first FET 101 (for example, 3 volts) is applied to the first control terminal CT 1 and zero volt is applied to the second control terminal CT2 simultaneously, then the first FET 101 turns on and the second FET 102 turns off. At this time a current generated by applying the first control voltage flows through the gate and the source of the first FET 101, and then through the third resistor 107 and the second diode 106. Finally, the current reaches the second control terminal CT2. The current generates a voltage drop. In the same way a current generated by applying a positive voltage as the second control voltage reaches to the first control terminal CT1 where zero volts is applied. Switching applied voltage to the first control terminal CT1 and the second control terminal CT2 enables to switch the connection with the common signal terminal T3 to either the signal terminals T1 or T2.

### CITATION LIST

### Patent Literature

Patent Literature Publication 1: JP Patent No. 3539106
Patent Literature Publication 2: JP-A-2007-184981

### SUMMARY OF THE INVENTION

Meanwhile, in recent years MOSFET (Metal-Oxide-Semiconductor Field Effect Transistor) has been employed for high frequency switch circuits. Conventional MOSFET fabricated on low resistive silicon substrate is not suitable for high frequency switch circuits. However, integrating high insulating substrates and fine silicon process such as SOS (silicon on sapphire) or SOI (silicon on insulator) has enabled the high frequency switch circuits equal to or better than the high frequency switch circuit fabricated by GaAs. As a result, employing MOSFET to high frequency switch circuits has been proceeding.

However, in a conventional circuit configuration as illustrated in FIG. 7, a current generated by applying the control voltage to either the first control terminal CT1 or the second control terminal CT2 generates a voltage drop between the gate-to-source of either the first or the second FET 101 or 102. On the other hand, the gate-to-source of MOSFET is isolated and has no diode characteristics. Therefore, just putting MOSFET on the conventional circuit configuration as shown in FIG. 7 will fail to operate as switch circuits. That is, in the conventional circuitry as shown in FIG. 7, a current blocked by MOSFET is also unable to flow through each diode (105, 106) which is connected reversely from each control terminal (CT1, CT2) and without applying another voltage source, it will become difficult to confirm the voltage of each source terminal for each FET (101, 102).

In order to solve the above-described problem, the present invention was devised. Accordingly, an object of the present invention is to provide high frequency switch circuits capable of executing a high-performance switching operation at low power consumption as well as at low cost without applying another voltage source.

According to one aspect of the present invention for providing a solution to the above-discussed problem, there is provided a high frequency switch circuit that makes use of a first control voltage applied to a first control terminal for controlling the connection between a common signal terminal and a first signal terminal and/or a second control voltage applied to a second control terminal for controlling the connection between the common signal terminal and a second signal terminal, whereby to selectively switch the connection of the common signal terminal to either the first signal terminal or the second signal terminal, the high frequency switch circuit comprising: a first signal section including a first MOSFET circuit one of whose main terminals is connected to the common signal terminal, the other of whose main terminals is connected to the first signal terminal and whose gate terminal is connected to the first control terminal, and a first rectifier circuit including at least one rectifier element one of whose ends is connected between the gate terminal of the first MOSFET circuit and the first control terminal and the other of whose ends is connected to ground, whereby the direction from the first control terminal towards ground is a forward direction; a second signal section including a second MOSFET circuit one of whose main terminals is connected to the common signal terminal, the other of whose main terminals is connected to the second signal terminal and whose gate terminal is connected to the second control terminal, and a second rectifier circuit including at least one rectifier element one of whose ends is connected between the gate terminal of the second MOSFET circuit and the second control terminal and the other of whose ends is connected to ground, whereby the direction from the second control terminal towards ground is a forward direction; and a connecting section connecting the forward-current input terminal side of at least one of the rectifier elements of the first rectifier circuit and either one of the main terminal sides of the first MOSFET circuit, and connecting the forward-current input terminal side of at least one of the rectifier elements of the second rectifier circuit and either one of the main terminal sides of the second MOSFET circuit.

According to the above-described configuration, the first and the second rectifier circuits are arranged respectively between the first control terminal and ground and between the second control terminal and ground so that the direction from each control terminal towards ground is a forward direction. Therefore, upon application of either the first or the second control voltage to either the first or the second control terminal, either the first or the second rectifier circuit causes either the first or the second control voltage to drop to an appropriate level of voltage. Thereafter, a current flows from either the first or the second control terminal to a channel leading to one of the main terminals of either the first or the second MOSFET circuit by way of either the first or the second rectifier circuit. This produces a gate-to-source voltage drop in either the first or the second MOSFET circuit, thereby making it possible that the switching operation is performed in an adequate manner. Furthermore, the dropped voltage in either the first or the second rectifier circuit corresponds with the threshold voltage of the rectifier element. Therefore, even if the first and the second control voltages vary in voltage value, both the value of the applied voltage to the main terminal of the first MOSFET circuit and the voltage value of the applied voltage to the main terminal of the second MOSFET can be held constant. This enables the switch circuit to operate more stably. In addition, by using the MOSFET as an element for ON/OFF switching connection between the common signal terminal and the first or the second signal terminal, it becomes possible to fabricate a low power consumption and high performance switch circuit at low cost. Accordingly, without use of any power supply source other than the control voltage, it is possible to inexpensively perform a low power consumption and high performance switching operation.

It may be arranged that the connecting section comprises a common connecting section connecting the forward-current input terminal side of at least one of the rectifier elements of the first rectifier circuit and the forward-current input terminal side of at least one of the rectifier elements of the second rectifier circuit, and a common resistor circuit arranged between the common connecting section and the common signal terminal. By this arrangement, it can be arranged that wiring for connection between the first control terminal and the one main terminal of the first MOSFET circuit and wiring for connection between the second control terminal and the one main terminal of the second MOSFET circuit are made common, thereby reducing the length of wiring to achieve downsizing of the circuit.

Further, it may be arranged that the common resistor circuit includes a voltage-division resistor element for dividing the voltage in the connecting section. By this arrangement, regardless of the value of the first control voltage and the value of the second control voltage and/or the value of the voltage output from the first rectifier circuit and the value of the voltage output from the second rectifier circuit, the applied voltage to ones of the main terminals (that is, the applied voltage to the common signal terminal) can optimally be regulated.

It may be arranged that the first and the second rectifier circuits each contain at least two rectifier elements interconnected in series, and wherein the connecting section is configured to connect either one of the main terminal sides of the first MOSFET circuit and a portion between the two rectifier elements interconnected in series in the first rectifier circuit, and to connect either one of the main terminal sides of the second MOSFET circuit and a portion between the two rectifier elements interconnected in series in the second rectifier circuit. By this arrangement, it becomes possible to provide at least one rectifier element in a channel between each of the first and second control terminals and one of the main terminals of each of the first and second MOSFET circuits, thereby preventing backflow of a current to the first and the second control terminals. This achieves reduction in power consumption.

It may be arranged that the connecting section is configured to connect the forward-current input terminal side of at least one of the rectifier elements of the first rectifier circuit and the first signal terminal side of the main terminals of the first MOSFET circuit, and to connect the forward-current input terminal side of at least one of the rectifier elements of the second rectifier circuit and the second signal terminal side of the main terminals of the second MOSFET circuit. Also by this arrangement, it is possible to allow, based on the voltage by either the first or the second control voltage, a current to flow from either the first or the second control terminal to one of the main terminals of either the first or the second MOSFET circuit, whereby it is made possible that the switching operation can adequately be performed.

It may be arranged that the first and the second MOSFET circuits each have a MOSFET element and a resistor element which is arranged between the main terminals of the MOSFET element so as to maintain the voltage between the main terminals of the MOSFET element constant in the absence of a current passing through the MOSFET element. By this arrangement, even when the MOSFET elements are in the OFF state, it is possible to keep the voltage between the main terminals of each MOSFET element constant.

It may be arranged that the high frequency switch circuit further comprises at least one further signal section which has the same configuration as the second signal section and which switches the connection of the common signal terminal to at least one further signal terminal By this arrangement, even when it is arranged that there are provided three or more signal terminals (for example, SP3T, SP4T, etc.) between which the connection of the common signal terminal is selectively switched, it is possible to perform a high-performance switching operation not only at low power consumption but also at low cost without use of any power supply source other than the control voltage.

In addition, according to another aspect of the present invention, there is provided a high frequency switch circuit that makes use of a first control voltage applied to a first control terminal for controlling the connection between a common signal terminal and a first signal terminal and/or a second control voltage applied to a second control terminal for controlling the connection between the common signal terminal and a second signal terminal, whereby to selectively switch the connection of the common signal terminal to either the first signal terminal or the second signal terminal, the high frequency switch circuit comprising: a first MOSFET circuit one of whose main terminals is connected to the common signal terminal, the other of whose main terminals is connected to the first signal terminal and whose gate terminal is connected to the first control terminal; a second MOSFET circuit one of whose main terminals is connected to the common signal terminal, the other of whose main terminals is connected to the second signal terminal and whose gate terminal is connected to the second control terminal; a first resistor circuit one of whose ends is connected between the gate terminal of the first MOSFET circuit and the first control terminal; a second resistor circuit one of whose ends is connected between the gate terminal of the second MOSFET circuit and the second control terminal; a common connecting section connecting the other end of the first resistor circuit and the other end of the second resistor circuit; and a common resistor circuit arranged between the common connecting section and the common signal terminal.

According to the above-described configuration, the first and the second rectifier circuits are arranged respectively between the first control terminal and ground and between the second control terminal and ground. Therefore, upon application of either the first or the second control voltage to either the first or the second control terminal, either the first or the second rectifier circuit causes either the first or the second control voltage to drop to an appropriate level of voltage. Thereafter, a current flows from either the first or the second control terminal to a channel leading to one of the main terminals of either the first or the second MOSFET circuit by way of either the first or the second rectifier circuit. This results in a gate-to-source voltage drop in either the first or the second MOSFET circuit, thereby making it possible that the switching operation is performed in an adequate manner. In addition, by using the MOSFET as an element for ON/OFF switching connection between the common signal terminal and the first or the second signal terminal, it becomes possible to inexpensively fabricate a low power consumption and high performance switch circuit. Accordingly, without use of any power supply source other than the control voltage, it is possible to inexpensively perform low power consumption and high performance switching operation.

The present invention is configured as has been described above and accordingly provides such an advantageous effect that without use of any power supply source other than the control voltage, it is possible to achieve a high-performance switching operation not only at low power consumption but also at low cost.

These objects as well as other objects, features and advantages of the present invention will become apparent to those skilled in the art from the following detailed description of the preferred embodiments with reference to the accompanying drawings.

### BRIEF DESCRIPTION OF THE DRAWINGS

In the drawings:

FIG. 1 is a circuit diagram showing a schematic configuration of a high frequency switch circuit according to a first embodiment of the present invention;

FIG. 2 is a circuit diagram showing a further detailed configuration of the switch circuit shown in FIG. 1;

FIG. 3 is a graph showing the characteristic against the applied voltage to the switch circuit shown in FIG. 2;

FIG. 4 is a circuit diagram showing a schematic configuration of a high frequency switch circuit according to a second embodiment of the present invention;

FIG. 5 is a circuit diagram showing a schematic configuration of a high frequency switch circuit according to a third embodiment of the present invention;

FIG. 6 is a circuit diagram showing a schematic configuration of a high frequency switch circuit according to a fourth embodiment of the present invention; and

FIG. 7 is a circuit diagram showing a schematic configuration of a conventional high frequency switch circuit.

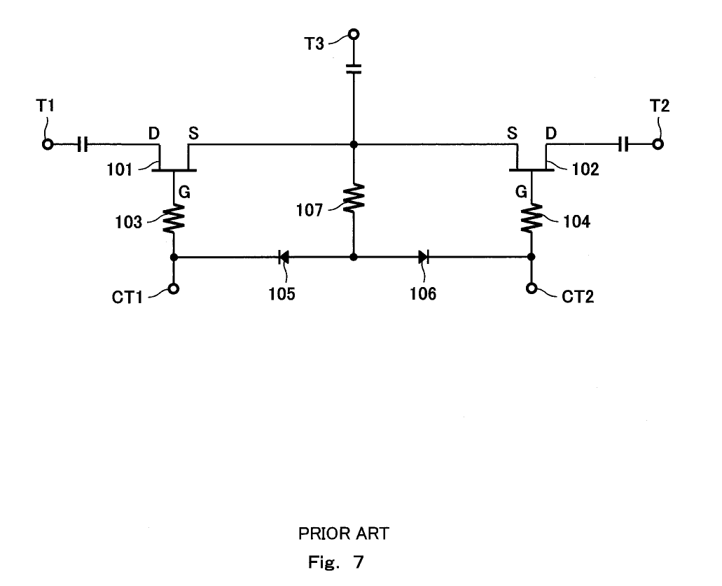

### DETAILED DESCRIPTION OF THE PREFERRED EMBODIMENTS

Hereinafter, a description will be given in regard to embodiments of the high frequency switch circuit according to the present invention with reference to the drawing figures. In addition, the same reference numerals are used throughout the drawing figures to refer to the same or like elements and accordingly their redundant description will be omitted.

### First Embodiment

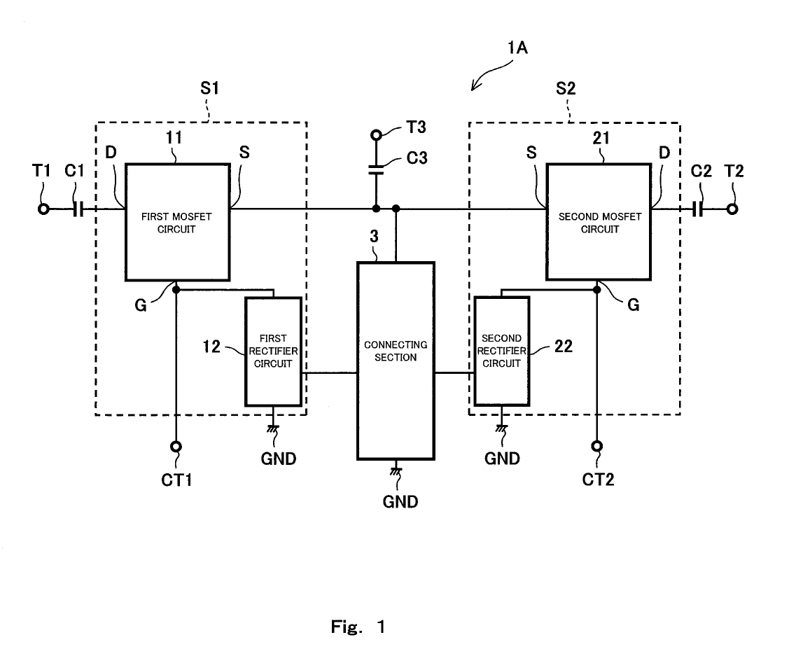

In the first place, a description will be given in regard to a high frequency switch circuit according to a first embodiment of the present invention. FIG. 1 is a circuit diagram showing a schematic configuration of a high frequency switch circuit according to the first embodiment of the present invention. As shown in FIG. 1, the switch circuit 1A of the present embodiment is configured as a high frequency switch circuit that makes use of a first control voltage VC1 applied to a first control terminal CT1 that controls the connection between a common signal terminal T3 and a first signal terminal T1 and/or a second control voltage VC2 applied to a second control terminal CT2 that controls the connection between the common signal terminal T3 and a second signal terminal T2, thereby to effect such switching between the first signal terminal T1 and the second signal terminal T2 that either one of the first signal terminal T1 and the second signal terminal T2 is selectively connected to the common signal terminal T3. The switch circuit 1A includes a first signal section S1 that switches between connecting and disconnecting the first signal terminal T1 and the common signal terminal T3 and a second signal section S2 that switches between connecting and disconnecting the second signal terminal T2 and the common signal terminal T3.

The first signal section S1 includes a first MOSFET circuit 11. One of main terminals of the first MOSFET circuit 11 (the source terminal in the present embodiment) is connected to the common signal terminal T3 whereas the other main terminal is connected to the first signal terminal T1. A first capacitor element C1 is provided between the first signal terminal T1 and the drain terminal of the first MOSFET circuit 11. The first capacitor element C1 is configured to block a direct-current component of a signal. Further, a common capacitor element C3 is provided between the common signal terminal T3 and the source terminal of the first MOSFET circuit 11. The common capacitor element C3 is configured to block a direct-current component of a signal. The first control terminal CT1 is provided at the gate terminal of the first MOSFET circuit 11.

The first signal section S1 further includes a first rectifier circuit 12. One end of the first rectifier circuit 12 is connected between the gate terminal of the first MOSFET circuit 11 and the first control terminal CT1 whereas the other end is connected to the ground GND. The first rectifier circuit 12 has at least one or more rectifier elements (as will be described), and is configured such that the direction from the first control terminal CT1 towards the ground GND is a forward direction.

Likewise, the second signal section S2 includes a second MOSFET circuit 21. One of main terminals of the second MOSFET circuit 21 (the source terminal in the present embodiment) is connected to the common signal terminal T3 whereas the other main terminal is connected to the second signal terminal T2. A second capacitor element C2 is provided between the second signal terminal T2 and the drain terminal of the second MOSFET circuit 21. The second capacitor element C2 is configured to block a direct-current component of a signal. In addition, the common signal terminal T3 and the source terminal of the second MOSFET circuit 21 are interconnected through the common capacitor element C3. The second control terminal CT2 is provided at the gate terminal of the second MOSFET circuit 21.

The first signal section S2 further includes a second rectifier circuit 22. One end of the second rectifier circuit 22 is connected between the gate terminal of the second MOSFET circuit 21 and the second control terminal CT2 whereas the other end is connected to the ground GND. The second rectifier circuit 22 has at least one or more rectifier elements (as will be described), and is configured such that the direction from the second control terminal CT2 towards the ground GND is a forward direction.

The switch circuit 1A of the present embodiment has a connecting section 3. The connecting section 3 connects the forward current input terminal side of at least one of the first rectifier circuit 12 and either one of the main terminals of the first MOSFET circuit 11 (the source terminal in the present embodiment). Further, the connecting section 3 connects the forward current input terminal side of at least one of the second rectifier circuit 22 and either one of the main terminals of the second MOSFET circuit 21 (the source terminal in the present embodiment).

According to the above-described configuration, the first and the second rectifier circuits 12 and 22 are arranged respectively between the first control terminal CT1 and the ground GND and between the second control terminal CT2 and the ground GND so that the direction from each of the first and the second control terminals CT1 and CT2 towards the ground GND is a forward direction. Therefore, upon application of either the first or the second control voltage VC1 or VC2 to either the first or the second control terminal CT1 or CT2, either the first or the second rectifier circuit 12 or 22 causes either the first or the second control voltage VC1 or VC2 to drop to an appropriate level of voltage. Thereafter, a current flows from either the first or the second control terminal CT 1 or CT2 to a channel leading to the source terminal of either the first or the second MOSFET circuit 11 or 21 by way of either the first or the second rectifier circuit 12 or 22. This produces a gate-to-source voltage drop in either the first or the second MOSFET circuit 11 or 21, thereby making it possible to perform the switching operation in an adequate manner. Furthermore, the dropped voltage in either the first or the second rectifier circuits 12 or 22 corresponds with the threshold voltage of the rectifier element thereof. Therefore, even if the values of the first and the second control voltages VC1 and VC2 vary, both the value of the applied voltage to the main terminal of the first MOSFET circuits 11 and the value of the applied voltage to the main terminal of the second MOSFET circuits 21 can be held constant. This enables the switch circuit 1A to operate more stably. In addition, by using MOSFET as an element for ON/OFF switching connection between the common signal terminal T3 and the first or the second signal terminal T1 or T2, it becomes possible to fabricate a low power consumption and high-performance switch circuit 1A at low cost. Accordingly, without use of any power supply source other than the control voltage, it is possible to inexpensively perform low power consumption and high performance switching operation.

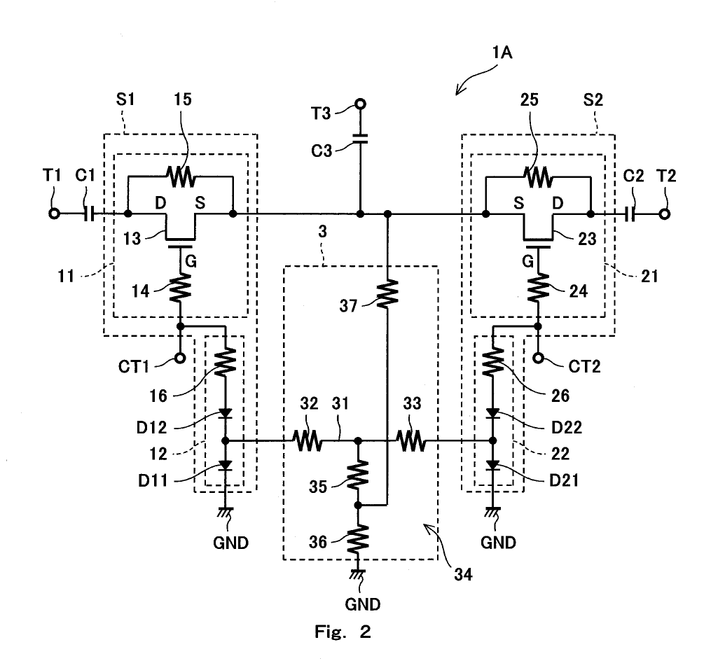

A more detailed description will be given in regard to the configuration of the present embodiment. FIG. 2 is a circuit diagram showing a further detailed configuration of the switch circuit shown in FIG. 1. As shown in FIG. 2, in the present embodiment, the first MOSFET circuit 11 includes a MOSFET element 13, a first resistor element 14 disposed between the first control terminal CT1 and the gate terminal of the MOSFET element 13 and a second resistor element 15 disposed between the main terminals (the source terminal and the drain terminal) of the MOSFET element 13. The first resistor element 14 is provided so as to protect the gate terminal of the MOSFET element 13 from application of an excess voltage (for example, the resistance value of the first resistor element 14 is set in the range of from about 10 kΩ to about 200 kΩ). In addition, the second resistor element 15 is provided so as to hold the voltage between the main terminals of the MOSFET element 13 constant when the MOSFET element 13 is in the OFF state (when no current flows therethrough). Furthermore, the second resistor element 15 has a higher resistance value than the ON resistance value of the MOSFET element 13 so that no current flows through the resistor when the MOSFET element 13 is in the ON state (when a current flows therethrough). For example, if the ON resistance value of the MOSFET element 13 is equal to or less than about 3 kΩ, then the resistance value of the second resistor element 15 is set in the range of from about 10 kΩ to about 100 kΩ.

The second MOSFET circuit 21 is also configured similarly to the first MOSFET circuit 11. More specifically, the second MOSFET circuit 21 includes a MOSFET element 23, a first resistor element 24 and a second resistor element 25.

In addition, one end of the first rectifier circuit 12 is connected between the first resistor element 14 connected to the gate terminal of the first MOSFET circuit 11 and the first control terminal CT1 whereas the other end of the first rectifier circuit 12 is connected to the ground GND (zero volts). In the first rectifier circuit 12, two rectifier elements D11 and D12 are connected in series to the ground GND so that the direction from the first control terminal CT1 towards the ground GND is a forward direction. More specifically, the rectifier elements D11 and D12 are formed by Schottky diodes. The rectifier element D11 is connected at its cathode terminal to the ground GND while the rectifier element D12 is connected at its cathode terminal to the anode terminal of the rectifier element D11. A third resistor element 16 is disposed between the anode terminal of the rectifier element D12 and the first control terminal CT1. The third resistor element 16 is configured to cause the applied voltage to the rectifier elements D11 and D12 to drop, thereby to reduce the amount of current flowing through the rectifier elements D11 and D12. For example, the resistance value of third resistor element 16 is set in the range of from about 1 kΩ to about 30 kΩ.

The second rectifier circuit 22 is also configured similarly to the first rectifier circuit 12. More specifically, the second rectifier circuit 22 includes two rectifier elements D21 and D22 and a third resistor element 26.

In addition, the rectifier elements D11, D12, D21 and D22 in the present embodiment are formed by Schottky diodes, which, however, should not be considered limitative. For example, these rectifier elements may be formed by any of diode elements other than Schottky diodes, bipolar transistors and FETs as long as they exhibit diode characteristics.

In the present embodiment, the connecting section 3 has a common connecting section 31 to which the forward-current input terminal side of at least one of the rectifier elements D11 and D12 of the first rectifier circuit 12 and the forward current input terminal side of at least one of the rectifier elements D21 and D22 of the second rectifier circuit 22 are connected. In the present embodiment, the anode terminal of the rectifier element D11 and the anode terminal of the rectifier element D21 are interconnected by the common connecting section 31. In other words, the common connecting section 31 connects a portion between the rectifier elements D11 and D12 interconnected in series and a portion between the rectifier elements D21 and D22 interconnected in series. The common connecting section 31 is provided with fourth resistor elements 32 and 33. The fourth resistor elements 32 and 33 reduce the first control voltage VC1 and the second control voltage VC1 respectively, to thereby lessen the applied voltage to each of the rectifier elements D11, D12, D21 and D22 so that the amount of current flowing through each rectifier element is reduced (for example, resistance values of the fourth resistor elements 32 and 33 are set in the range from about 10 kΩ to about 200 kΩ).

In addition, a common resistor circuit 34 is provided between the common connecting section 31 and the common signal terminal T3. The common resistor circuit 34 includes voltage-division resistor elements 35 and 36 for dividing the voltage in the connecting section 3. These voltage-division resistor elements 35 and 36 are connected together in series. One of them, i.e., the voltage-division resistor element 35, is connected to the common connecting section 31 whereas the other of them, i.e., the voltage-division resistor element 36 is connected to the ground GND. The common resistor circuit 34 further includes a fifth resistor element 37 one of whose ends is connected between the voltage-division resistor elements 35 and 36 and the other of whose ends is connected to one of the main terminals of the first MOSFET circuit 11 (the source terminals thereof) as well as to one of the main terminals of the second MOSFET circuit 21 (the source terminal thereof). The fifth resistor element 37 prevents the alternating current signal from the common signal terminal T3 from flowing to the ground GND connected to the voltage-division resistor element 36 via the connecting section 3 (for example, a resistance value of the fifth resistor element 37 is set in the range of from about 10 kΩ to 200 kΩ).

Here, a description will be given in regard to an example of the operation of the switch circuit 1A having the above configuration. In this operation example, a description will be given in regard to such an operational mode that the first MOSFET circuit 11 is turned on while the second MOSFET circuit 21 is turned off, thereby to establish connection between the first signal terminal T1 and the common signal terminal T3. In the present embodiment, the rectifier elements D11, D12, D21 and D22 each have a threshold voltage of 0.6 volts.

In the first place, a voltage of 3 volts (the first control voltage VC1=3 volts) is applied, as an ON signal, to the first control terminal CT1 while a voltage of zero volts (the second control voltage VC2=0 volts) is applied, as an OFF signal, to the second control terminal CT2. Upon application of such a positive first control voltage VC1 (=3 volts) to the first control terminal CT1, a current flows through a channel connecting the third resistor element 16 and the rectifier elements D11 and D12, thereby generating a difference in potential. In the present embodiment, since the threshold voltage of the rectifier element D11 is 0.6 volts and the ground GND voltage is zero volts, the voltage at the anode of the rectifier element D11 is 0.6 volts.

On the other hand, the second control voltage VC2 applied to the second control terminal CT2 is zero volts. Therefore, the second control voltage VC2 is lower than the threshold voltage (1.2 volts) of the rectifier elements D21 and D22 interconnected in series, because of which no current flows through the rectifier elements D21 and D22 and accordingly no potential difference will take place. In addition, in the MOSFET element 23 comprising the second MOSFET circuit 21, the gate terminal is isolated from the source and the drain terminals and therefore there exists no channel through which a current from the second control terminal CT2 flows.

As described above, the voltage between the rectifier element D11 and the rectifier element D12 in the first signal section S1 is 0.6 volts. On the other hand, no current flows through the rectifier elements D21 and D22 in the second signal section S2, the rectifier elements D21 and D22 being connected to the rectifier elements D11 and D12 via the common connecting section 31. Consequently, the voltage between the rectifier element D21 and the rectifier element D22 in the second signal section S2 is also 0.6 volts.

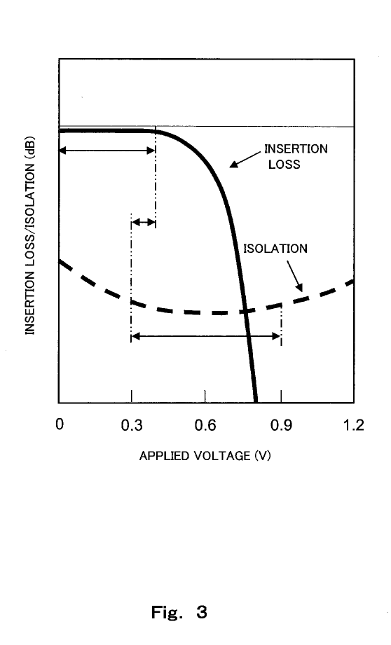

Here, a description will be given in regard to the characteristic against the applied voltage (the applied voltage to the source terminal or the drain terminal of each of the MOSFET elements 13 and 23) of the switch circuit 1A employed in the present embodiment. FIG. 3 is a graph showing the characteristic against the applied voltage of the switch circuit shown in FIG. 2. Referring to FIG. 3, there is shown, as the characteristic against the applied voltage, an isolation characteristic representing the characteristic when the MOSFET elements 13 and 23 are in the OFF state and an insertion loss characteristic when the MOSFET elements 13 and 23 are in the ON state.

The isolation characteristic represents the input/output voltage ratio between the common signal terminal T3 and the first or second signal terminals T1 or T2 when the MOSFET elements 13 and 23 are turned off and therefore represents the degree of signal leakage. The isolation characteristic represents that the greater (“the lower” in the graph of FIG. 3) the absolute value of isolation, the less the signal leakage. According to FIG. 3, the range of from about 0.3 volts to about 0.9 volts is a preferable range for the isolation characteristic. On the other hand, the insertion loss characteristic represents the input/output voltage ratio between the common signal terminal T3 and the first or second signal terminals T1 or T2 when the MOSFET elements 13 and 23 are turned on and therefore represents the degree of signal loss. The insertion loss characteristic represents that the smaller (the “upper” in the graph of FIG. 3) the absolute value of insertion loss, the less the insertion loss. According to FIG. 3, the range of from about 0 volts to about 0.4 volts is a preferable range for the signal loss characteristic.

In the switch circuit 1A of the present embodiment, the second resistor element 15 connects between the drain and the source terminals of the MOSFET element 13 while the second resistor element 25 connects between the drain and the source terminals of the MOSFET element 23, whereby regardless of whether the MOSFET elements 13 and 23 are turned on or off, the same voltage is applied to the drain and source terminals. Accordingly, when taking into account such a normal operating condition that one of the MOSFET elements 13 and 23 turns on while the other turns off, it is preferred that the applied voltage to the source terminals of the MOSFET element 13 and 23 via the connecting section 3 is set in the range from about 0.3 volts to about 0.4 volts. Such a range is a suitable range for both the isolation characteristic and the insertion loss characteristic. However, when a preference is given to either the isolation characteristic or the insertion loss characteristic, there is no need to employ such a range. For example, in favor of the signal loss characteristic, the applied voltage may be set in the range from about 0.1 volts to about 0.4 volts.

In addition, in the present embodiment, once the control voltage (3 volts) serving as an ON signal is applied to either one of the first and the second control terminals CT1 and CT2, both the voltage applied between the rectifier elements D11 and D12 and the voltage applied between the rectifier elements D21 and D22 are 0.6 volts. Thereafter, even if both the control voltage of the control terminal CT1 and the control voltage of the second control terminal CT2 change to zero volts, the voltage between the rectifier elements D11 and D12 and the voltage between the rectifier elements D21 and D22 are held at 0.6 volts because of the absence of a channel through which current flows to the first and the second control terminals CT 1 and CT2.

Therefore, by causing the voltage between the rectifier elements D11 and D12 and the voltage between the rectifier elements D21 and D22 to drop to a predetermined level of voltage in consideration of the isolation characteristic and the insertion loss characteristic, it becomes possible that the applied voltage to the source terminal of each of the MOSFET elements 13 and 23 can be set within a preferable range. More specifically, by proper setting of the resistance value of the voltage-division resistor elements 35 and 36, the voltage between the rectifier elements D11 and D12 and the voltage between the rectifier elements D21 and D22 are divided by the voltage-division resistor elements 35 and 36 respectively, whereby it is made possible that the voltage falling within the above-discussed preferable range (for example, 0.4 volts) can be applied to the source terminals of the MOSFET elements 13 and 23.

As described above, upon application of the voltage to the source terminals of the MOSFET elements 13 and 23, a difference in potential occurs between the gate terminal voltage (3 volts) of the first MOSFET circuit 11 corresponding to the first control voltage VC1 and the source terminal voltage (0.4 volts) of the first MOSFET circuit 11, the difference in potential being in excess of the threshold voltage of the MOSFET element 13. As a result, the first MOSFET circuit 11 turns on and the common signal terminal T3 and the first signal terminal T1 are interconnected, whereby it becomes possible to transfer a high frequency signal. On the other hand, no difference in potential occurs between the gate terminal voltage (0 volts) of the second MOSFET circuit 21 corresponding to the second control voltage VC2 and the source terminal voltage (0.4 volts) of the second MOSFET circuit 21, no difference in potential being in excess of the threshold voltage of the MOSFET element 23. As a result, the second MOSFET circuit 21 remains tuned off and the state of disconnection between the common signal terminal T3 and the second signal terminal T2 is maintained.

Also when the OFF signal, 0 volts, is applied to the first control terminal CT1 (the first control signal VC1 is set to 0 volts) while the ON signal, a positive voltage (3 volts), is applied to the second control terminal CT2, the resulting operation is the same as above, that is, the second MOSFET circuit 21 is turned on whereas the first MOSFET circuit 11 is turned off.

As described above, in the present embodiment, the voltage caused to drop in the first rectifier circuit 12 becomes a voltage (a clamped voltage from the ground potential) corresponding to the threshold voltage of the rectifier element D11, and the voltage caused to drop in the second rectifier circuit 22 becomes a voltage (a clamped voltage from the ground potential) corresponding to the threshold voltage of the rectifier element D22. Therefore, even if the values of the first control voltage VC1 and the voltage value of the second control voltage VC2 vary, the value of the applied voltage to the main terminals of the first and the second MOSFET circuits 11 and 21 can be held constant, whereby the switch circuit 1A can be operated more stably. Furthermore, since the voltage between the rectifier elements D11 and D12 and the voltage between the rectifier elements D21 and D22 can be dropped respectively by the voltage-division resistor elements 35 and 36, this makes it possible to optimally regulate the applied voltage to the source terminals (i.e., the common signal terminal T3) of the first and the second MOSFET circuits 11 and 21, regardless of the voltage value of the first and the second control voltages VC1 and VC2 and the voltage value of the voltage between the rectifier elements. Additionally, since delicate setting of the first and the second MOSFET circuits 11 and 21 is implemented by selecting various resistance values of the voltage-division resistor elements 35 and 36, it becomes possible that optimal voltages are applied to the first and the second MOSFET circuits 11 and 21, regardless of whether the first and the second MOSFET circuits 11 and 21 are tuned on or off.

Furthermore, by arranging the rectifier element D12 between the first control terminal CT1 and the connecting section 3 and arranging the rectifier element D22 respectively between the second control terminal CT2 and the connecting section 3, it becomes possible to prevent backflow of a current to the first and the second control terminals CT1 and CT2, thereby making it possible to reduce the power consumption to a further extent. In addition, since each rectifier circuit (12, 22) is provided with a plurality of rectifier elements, this makes it possible to absorb variation in voltage due to the temperature.

Additionally, the anode terminal of the rectifier element D11 and the anode terminal of the rectifier element D21 are interconnected by the common connecting section 31, whereby it can be arranged that wiring for connection between the first control terminal CT1 and the one main terminal of the first MOSFET circuit 11 and wiring for connection between the second control terminal CT2 and the one main terminal of the second MOSFET circuit 21 are made common, thereby reducing the length of wiring to achieve downsizing of the circuit.

In addition, in the present embodiment, the description has been given in regard to such a configuration that one rectifier element D11 is connected between the ground GND and the common connecting section 31 and also one rectifier element D21 is connected between the ground GND and the common connecting section 31. However, it may be arranged that a plurality of rectifier elements are connected between the ground GND and the common connecting section 31. In other words, depending on the characteristics required respectively for rectifier elements and for MOSFET elements 13 and 23 to be used, one or more rectifier elements preferable for setting of the clamped voltage from the ground potential may be employed. In addition, in the present embodiment, the description has been given in regard to such a configuration that one rectifier element D11 is provided between the common connecting section 31 and the first control terminal CT1 and also one rectifier element D21 is provided between the common connecting section 31 and the second control terminal CT2. However, either plural rectifier elements may be respectively provided between the common connecting section 31 and the first control terminal CT1 and between the common connecting section 31 and the second control terminal, or otherwise no rectifier elements may be provided there.

### Second Embodiment

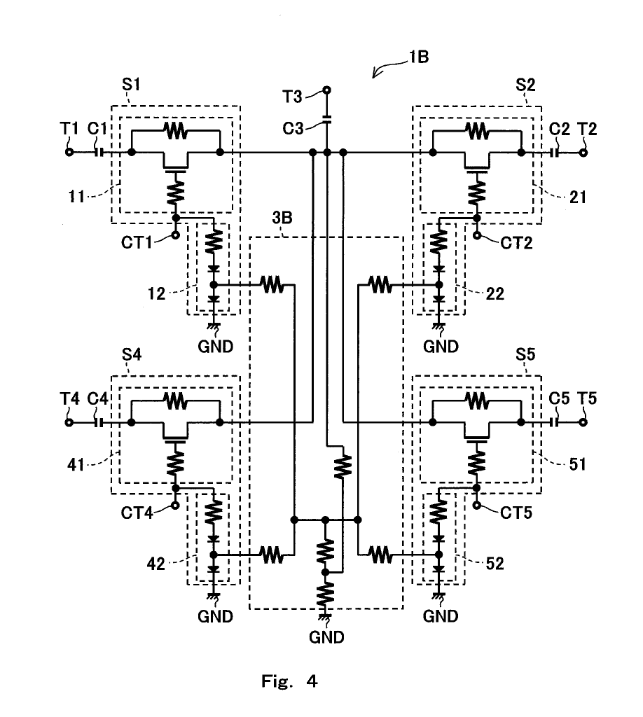

Next, a description will be given in regard to a high frequency switch circuit according to a second embodiment of the present invention. FIG. 4 is a circuit diagram showing a schematic configuration of a high frequency switch circuit according to the second embodiment of the present invention. In the present embodiment, the same reference numerals are used to refer to the same elements as the first embodiment, and their redundant description will be omitted accordingly. The switch circuit 1B of the second embodiment differs from the switch circuit 1A of the first embodiment in that the switch circuit 1B further includes at least one section (a third signal section S4 and a fourth signal section S5) having the same configuration as the second signal section S2 and which are provided for switching between the common signal terminal and at least one signal terminal (two signal terminals in the second embodiment, i.e., a third signal terminal T4 and a fourth signal terminal T5).

More specifically, the third signal section S4 includes a third MOSFET circuit 41. The third MOSFET circuit 41 is connected at its one main terminal to the common signal terminal T3, at its other main terminal to the third signal terminal T4 and at its gate terminal to a third control terminal CT4. The third signal section S4 further includes a third rectifier circuit 42. The third rectifier circuit 42 contains at least one rectifier element (two rectifier elements in the present embodiment) one of whose ends is connected between the gate terminal of the third MOSFET circuit 41 and the third control terminal CT4 and the other of whose ends is connected to the ground GND, whereby the direction from the third control terminal CT4 towards the ground GND is a forward direction. In addition, the fourth signal section S5 includes a fourth MOSFET circuit 51. The fourth MOSFET circuit 51 is connected at its one main terminal to the common signal terminal T3, at its other main terminal to the fourth signal terminal T5 and at its gate terminal to a fourth control terminal CT5. The fourth signal section S5 further includes a fourth rectifier circuit 52. The fourth rectifier circuit 52 contains at least one rectifier element (two rectifier elements in the present embodiment) one of whose ends is connected between the gate terminal of the fourth MOSFET circuit 51 and the fourth control terminal CT5 and the other of whose ends is connected to the ground GND, whereby the direction from the fourth control terminal CT5 towards the ground GND is a forward direction. In addition, a third capacitor element C4 is provided between the third signal terminal T4 and the drain terminal of the third MOSFET circuit 41, the third capacitor element C4 is configured to block of a direct-current component of a signal. Further, a fourth capacitor element C5 is provided between the fourth signal terminal T5 and the drain terminal of the fourth MOSFET circuit 51, the fourth capacitor element C5 is configured to block of a direct-current component of a signal.

Other than that the number of corresponding fourth resistor elements increases in conformity with the increase in the number of signal sections, the connecting section 3B of the present embodiment has the same configuration as that of the first embodiment. As just described, even in such a configuration that comprises more than three signal terminals (the signal terminals T1, T2, T3, T4) for switching of the connection with the common signal terminal T3 (for example, SP3T, SP4T, etc.), it is possible to perform high-performance switching operation at low power consumption as well as at low cost without use of any power supply source other than the control voltage.

### Third Embodiment

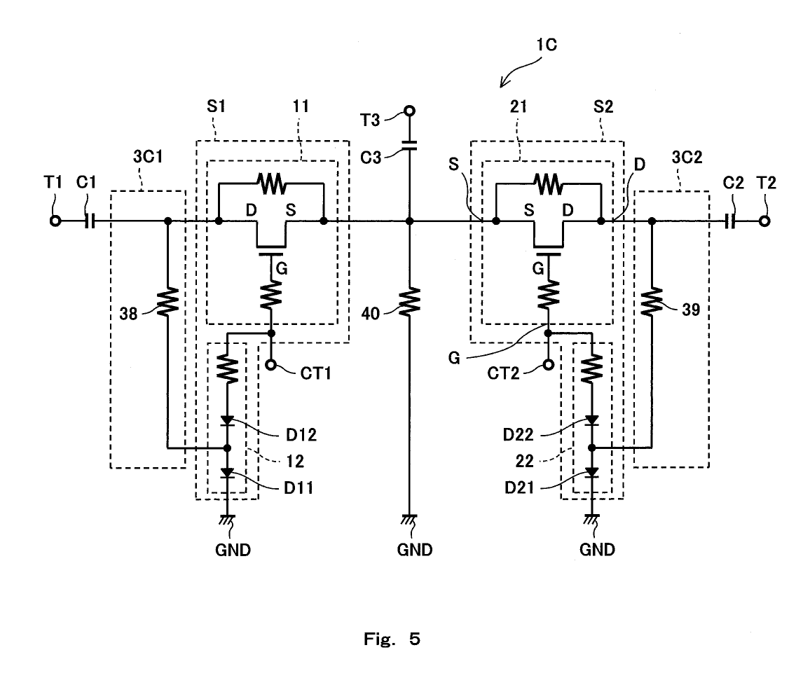

Next, a description will be given in regard to a high frequency switch circuit according to a third embodiment of the present invention. FIG. 5 is a circuit diagram showing a schematic configuration of a high frequency switch circuit according to the third embodiment of the present invention. In the present embodiment, the same reference numerals are used to refer to the same components as the first embodiment, and their redundant description will be omitted accordingly. The difference of the switch circuit 1C of the present embodiment from the switch circuit 1A of the first embodiment is that it has, as a connecting section, a first connecting section 3C1 and a second connecting section 3C2. The first connecting section 3C1 establishes connection between the forward current input terminal side of at least one of the rectifier elements of the first rectifier circuit 12 and the first signal terminal T1 side (the drain terminal of the first MOSFET circuit 11 in the present embodiment) of the main terminals of the first MOSFET circuit 11. On the other hand, the second connecting section 3C2 establishes connection between the forward current input terminal side of at least one of the rectifier elements of the second rectifier circuit 22 and the second signal terminal T2 side (the drain terminal of the second MOSFET circuit 21 in the present embodiment) of the main terminals of the second MOSFET circuit 21. More specifically, as shown in FIG. 5, the first and the second connecting sections 3C1 and 3C2 have a sixth resistor elements 38 and 39 respectively. The sixth resistor element 38 is provided between the anode terminal of the rectifier element D11 of the first rectifier circuit 12 and the drain terminal of the first MOSFET circuit 11 whereas the other sixth resistor element 39 is provided between the anode terminal of the rectifier element D21 of the second rectifier circuit 22 and the drain terminal of the second MOSFET circuit 21. In addition, the switch circuit 1C has a seventh resistor element 40 which is connected at its one end to the source terminals of the first and the second MOSFET circuits 11 and 21 and at its other end to the ground GND.

The sixth resistor elements 38 and 39 are used to lower the first and the second control voltages VC1 and VC2 respectively, like the fourth resistor elements 32 and 33 in the first embodiment. Accordingly, the applied voltage to each rectifier element (D11, D12, D21, D22) is reduced so that the amount of current flowing through these rectifier elements is reduced. In addition, the seventh resistor element 40 operates to prevent the AC signal from flowing to the ground GND from the common signal terminal T3, as it is for the fifth resistor element 37 in the first embodiment.

Also in the configuration of the present embodiment, for example, if a positive voltage (the first control voltage VC1=3 volts) is applied, as an ON signal, to the first control terminal CT1, the voltage clamped from the potential of the ground GND connected to the rectifier element D11 of the first rectifier circuit 12 by an amount corresponding to the threshold voltage of the rectifier element D11 is dropped by the sixth resistor element 38 then applied to the first MOSFET circuit 11. Accordingly, since based on the voltage by either the first or the second control voltage VC1 or VC2, a current is allowed to flow from either the first or the second control terminal CT1 or CT2 to one of the main terminals of either the first or the second MOSFET circuit 11 or 21, this makes it possible to perform a proper switching operation.

### Fourth Embodiment

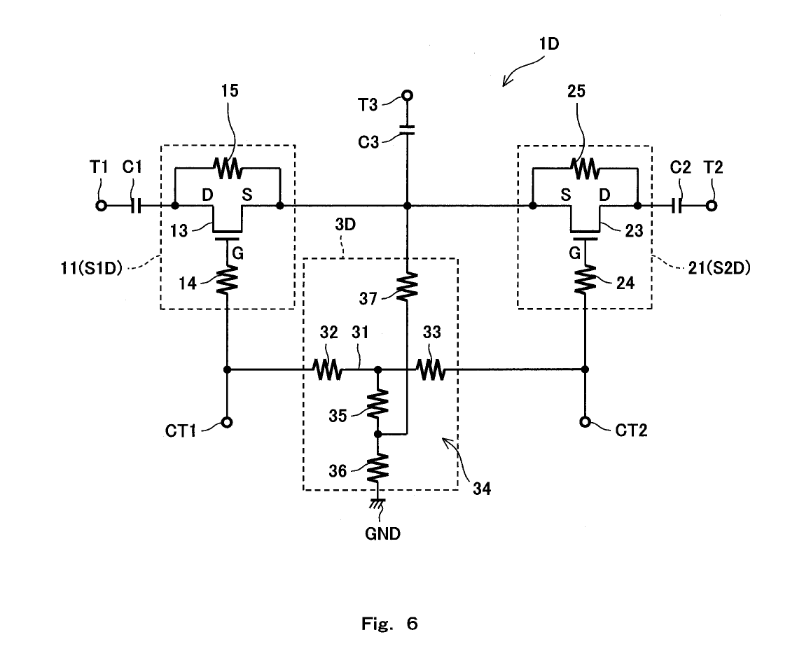

Next, a description will be given in regard to a high frequency switch circuit according to a fourth embodiment of the present invention. In the first, the second and the third embodiments, the signal section includes a rectifier circuit, and it is arranged that upon application of a control voltage as an ON signal to the control terminal, at least one rectifier element arranged in the rectifier circuit extracts, from the control voltage applied, a voltage clamped from the potential of the ground GND by an amount corresponding to the threshold voltage of the rectifier element. However, in the case where the applied voltage to the main terminal of the MOSFET element can be set using only a resistor circuit, e.g., in the case where variations in control voltage can be ignored, there is no need to arrange such a rectifier circuit. FIG. 6 is a circuit diagram showing a schematic configuration of a high frequency switch circuit according to the fourth embodiment of the present invention. In the present embodiment, the same reference numerals are used to refer to the same components as the first embodiment, and their redundant description will be omitted accordingly.

The high frequency switch circuit 1D of the present embodiment includes a first signal section S1D having a first MOSFET circuit 11 and a second signal section S2D having a second MOSFET circuit 21. In addition, the switch circuit 1D has a connecting section 3D with the same configuration as the connecting section 3 of the switch circuit 1A in the first embodiment, and the fourth resistor element 32 functions as a first resistor circuit which is connected at its one end between the gate terminal of the first MOSFET circuit 11 and the first control terminal CT1 whereas the fourth resistor element 33 functions as a second resistor circuit which is connected at its one end between the gate terminal of the second MOSFET circuit 21 and the second control terminal CT2.

According to the above-described configuration, the fourth resistor element 32 as a first resistor circuit is provided between the first control terminal CT1 and the ground GND connected to the voltage-division resistor element 36 and the fourth resistor element 33 as a second resistor circuit are provided between the second control terminal CT2 and the ground GND connected to the voltage-division resistor element 36. Therefore, upon application of either the first or the second control voltage VC1 or VC2 as an ON signal to either the first or the second control terminal CT1 or CT2, the first or the second control voltage VC1 or VC2 is dropped to a proper level of voltage by either the fourth resistor element 32 or the fourth resistor element 33. Thereafter, a current will flow from either the first or the second control terminal CT1 or CT2, through either the fourth resistor element 32 or the fourth resistor element 33 and then through the voltage-division resistor element 35 and the fifth resistor element 37 which together comprise the common resistor circuit 34, to a channel connected to the source terminal of either the first or the second MOSFET circuit 11 or 21. This provides a gate-to-source voltage drop in either the first or the second MOSFET circuit 11 or 21, thereby making it possible to properly perform a switching operation. Furthermore, by using of MOSFET as an element for ON/OFF switching connection between either the first or the second signal terminal T1 or T2 and the common signal terminal T3, it becomes possible to inexpensively fabricate a low power consumption and high performance switch circuit. Accordingly, without use of any power supply source other than the control voltage, it is possible to perform a high performance switching operation not only at low power consumption but also at low cost.

The foregoing description has been given in regard to the embodiments of the present invention. However, the present invention should not be limited to the above-described embodiments, and it will be appreciated by persons skilled in the art that modifications may be made without departing from the scope of the present invention. One such modification may comprise any combination of each constituent element with the other in the above-described embodiments.

Numerous modifications and alternative embodiments of the invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the spirit of the invention and all modifications which come within the scope of the appended claims are reserved.

### INDUSTRIAL APPLICABILITY

The present invention finds its application in performing a high-performance switching operation at lower power consumption as well as at low cost without use of any power supply source other than a control voltage in a high frequency switch circuit.

What is claimed is:

1. A high frequency switch circuit that makes use of a first control voltage applied to a first control terminal for controlling the connection between a common signal terminal and a first signal terminal and/or a second control voltage applied to a second control terminal for controlling the connection between the common signal terminal and a second signal terminal, whereby to selectively switch the connection of the common signal terminal to either the first signal terminal or the second signal terminal, the high frequency switch circuit comprising:
a first signal section including a first MOSFET circuit one of whose main terminals is connected to the common signal terminal, the other of whose main terminals is connected to the first signal terminal and whose gate terminal is connected to the first control terminal, and a first rectifier circuit including at least one rectifier element one of whose ends is connected between the gate terminal of the first MOSFET circuit and the first control terminal and the other of whose ends is connected to ground, whereby the direction from the first control terminal towards ground is a forward direction;
a second signal section including a second MOSFET circuit one of whose main terminals is connected to the common signal terminal, the other of whose main terminals is connected to the second signal terminal and whose gate terminal is connected to the second control terminal, and a second rectifier circuit including at least one rectifier element one of whose ends is connected between the gate terminal of the second MOSFET circuit and the second control terminal and the other of whose ends is connected to ground, whereby the direction from the second control terminal towards ground is a forward direction; and
a connecting section connecting the forward-current input terminal side of at least one of the rectifier elements of the first rectifier circuit and either one of the main terminal sides of the first MOSFET circuit, and connecting the forward-current input terminal side of at least one of the rectifier elements of the second rectifier circuit and either one of the main terminal sides of the second MOSFET circuit.

2. The high frequency switch circuit as set forth in claim 1, wherein the connecting section comprises a common connecting section connecting the forward-current input terminal side of at least one of the rectifier elements of the first rectifier circuit and the forward-current input terminal side of at least one of the rectifier elements of the second rectifier circuit, and a common resistor circuit arranged between the common connecting section and the common signal terminal.

3. The high frequency switch circuit as set forth in claim 2, wherein the common resistor circuit includes a voltage-division resistor element for dividing of the voltage in the connecting section.

4. The high frequency switch circuit as set forth in claim 1, wherein the first and the second rectifier circuits each contain at least two rectifier elements interconnected in series, and wherein the connecting section is configured to connect either one of the main terminal sides of the first MOSFET circuit and a portion between the two rectifier elements interconnected in series in the first rectifier circuit, and to connect either one of the main terminal sides of the second MOSFET circuit and a portion between the two rectifier elements interconnected in series in the second rectifier circuit.

5. The high frequency switch circuit as set forth in claim 1, wherein the connecting section is configured to connect the forward-current input terminal side of at least one of the rectifier elements of the first rectifier circuit and the first signal terminal side of the main terminals of the first MOSFET circuit, and to connect the forward-current input terminal side of at least one of the rectifier elements of the second rectifier circuit and the second signal terminal side of the main terminals of the second MOSFET circuit.

6. The high frequency switch circuit as set forth in claim 1, wherein the first and the second MOSFET circuits each have a MOSFET element and a resistor element which is arranged between the main terminals of the MOSFET element so as to maintain the voltage between the main terminals of the MOSFET element constant in the absence of a current passing through the MOSFET element.

7. The high frequency switch circuit as set forth in claim 1, further comprising at least one further signal section which has the same configuration as the second signal section and which switches the connection of the common signal terminal to at least one further signal terminal.

8. A high frequency switch circuit that makes use of a first control voltage applied to a first control terminal for controlling the connection between a common signal terminal and a first signal terminal and/or a second control voltage applied to a second control terminal for controlling the connection between the common signal terminal and a second signal terminal, whereby to selectively switch the connection of the common signal terminal to either the first signal terminal or the second signal terminal, the high frequency switch circuit comprising:
a first MOSFET circuit one of whose main terminals is connected to the common signal terminal, the other of whose main terminals is connected to the first signal terminal and whose gate terminal is connected to the first control terminal;
a second MOSFET circuit one of whose main terminals is connected to the common signal terminal, the other of whose main terminals is connected to the second signal terminal and whose gate terminal is connected to the second control terminal;
a first resistor circuit one of whose ends is connected between the gate terminal of the first MOSFET circuit and the first control terminal;
a second resistor circuit one of whose ends is connected between the gate terminal of the second MOSFET circuit and the second control terminal;
a common connecting section connecting the other end of the first resistor circuit and the other end of the second resistor circuit; and
a common resistor circuit arranged between the common connecting section and the common signal terminal.
